(19) United States
(12) Patent Application Publication
(10) Pub. No.: US 2009/0250007 A1
(43) Pub. Date: Oct. 8, 2009

(54) Apparatus for Depositing Thin Films Over Large-Area Substrates

(76) Inventors: Kug Weon Kim, Seoul (KR); Tai Joon Um, Seoul (KR); Young Cheol Joo, Chungcheongnam-do (KR); Sang Wook Lee, Gyeonggi-do (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/295,689

(22) PCT Filed: Jul. 30, 2007
(86) PCT No.: PCT/KR2007/003647

§ 371 Date: Jan. 13, 2009

(30) Foreign Application Priority Data
Aug. 8, 2006 (KR) 10-2006-0074543
Mar. 8, 2007 (KR) 10-2007-0022924

(51) Int. Cl. C23C 16/54

(52) U.S. Cl. 118/726

(57) ABSTRACT

An apparatus for increasing uniformity of thin films deposited on a substrate includes multiple deposition sources to accommodate and discharge evaporation material. A member supports the deposition sources in a selected arrangement. A heater can be used to apply heat to the deposition sources. In another embodiment, the apparatus can include a container to accommodate evaporation material. The container may include aperture at or near its center. A cover caps an opening of the container and includes multiple gas outlets. The apparatus further includes a heater disposed along an inner surface of the aperture and along an outer surface of the container.

### TECHNICAL FIELD

The present disclosure relates generally to thin film deposition devices and, more particularly, to apparatus for depositing thin films over large-area substrates.

### BRIEF DESCRIPTION OF THE DRAWINGS

The foregoing and other objects and features of the present disclosure will become more fully apparent from the following description and appended claims, taken in conjunction with the accompanying drawings. Understanding that these drawings depict only typical embodiments in accordance with the present disclosure and are, therefore, not to be considered limiting of its scope, the present disclosure will be described with additional specificity and detail through use of the accompanying drawings in which:

FIG. 1 is a top view of one embodiment of a rectangular apparatus in accordance with the present disclosure;

FIG. 2 is a perspective view of one embodiment of a rectangular apparatus in accordance with the present disclosure;

FIG. 3 is a top view of one embodiment of a circular apparatus in accordance with the present disclosure;

FIG. 4 is a perspective view of one embodiment of an apparatus having multiple linear deposition sources arranged in rows;

FIG. 5 is an exploded perspective view of one embodiment of an apparatus having a square crucible and an upper cover with circular outlets;

FIG. 6 is a top view of one embodiment of a square apparatus having larger point deposition sources at each corner;

FIG. 7 is a top view of one embodiment of a circular apparatus having additional point deposition sources along an outer circumference thereof;

FIG. 8 is top view of one embodiment of apparatus showing heater disposed in various support members thereof;

FIG. 9 is top view of another embodiment of apparatus showing heaters disposed in various support members thereof; and

FIG. 10 is a perspective view of one embodiment of a crucible having a heater embedded in a sidewall thereof.

### BACKGROUND

Recently, organic light emitting diodes (OLEDs) are increasingly being used in moving picture displays in light of their fast response, low power consumption, light weight, wide viewing angle, and the like. A thermal physical vapor deposition (PVD) process is generally used to form organic thin films and metal electrode layers when manufacturing OLEDs, such as monomer-series OLEDs.

In a typical PVD process, organic material is heated to a temperature where it vaporizes or sublimates. The vaporized organic material is then discharged from a deposition source onto a substrate to create a coating. In this way, the PVD process may form a metal layer and an organic layer, such as a charge transport layer and a charge injection layer, on the substrate. When manufacturing an OLED, variation in the film thickness of the organic layer has a relatively significant effect on the emissive brightness and emissive color of an OLED. Moreover, as the display area of OLEDs becomes larger, vapor deposition devices used to manufacture OLEDs must normally be adapted to create a uniform thin film over larger-area substrates, thereby making it more difficult to form a uniform deposition layer on the substrate.

In order to uniformly deposit organic material onto the large surface of the substrate, the deposition source may be moved in a horizontal direction or be rotated by a pre-determined angle against the substrate. As an example, a translation device may be used to move the deposition source relative to the substrate. Such a translation device may, however, be complicated and undesirably large as the area of the substrate increases. In addition, electrical wires (e.g., power cables) and cooling water may have to move with the translation device, making it even more complex. Movement of the deposition source may also damage the substrate and make it difficult to control the deposition temperature and deposition rate. These problems can become more severe as the area of the substrate increases, thereby making it more difficult to achieve uniform deposition over larger areas.

### SUMMARY

The present disclosure describes apparatus that can increase uniformity of thin films deposited on a substrate. In one embodiment, an apparatus includes multiple deposition sources to accommodate and discharge evaporation material. A member is provided to maintain the multiple deposition sources in a selected arrangement. A heater may be used to apply heat to the deposition sources.

In another embodiment, an apparatus may include a container to accommodate evaporation material. The container may have an arbitrary shape and may include an aperture at or near its center. A cover caps an opening of the container and includes multiple gas outlets having a selected arrangement. The apparatus may further include a heater having at least a position that is disposed along an inner surface of the aperture and along an outer surface of the container.

### DETAILED DESCRIPTION

It will be readily understood that the components of the present disclosure, as generally described and illustrated in the Figures herein, could be arranged and designed in a wide variety of different configurations. Thus, the following more detailed description of the embodiments of apparatus and methods in accordance with the present disclosure, as represented in the Figures, is not intended to limit the scope of the present claims, but is merely representative of certain examples of presently contemplated embodiments in accordance with the present disclosure. The presently described embodiments will be best understood by reference to the drawings, wherein like parts are designated by like numerals throughout.

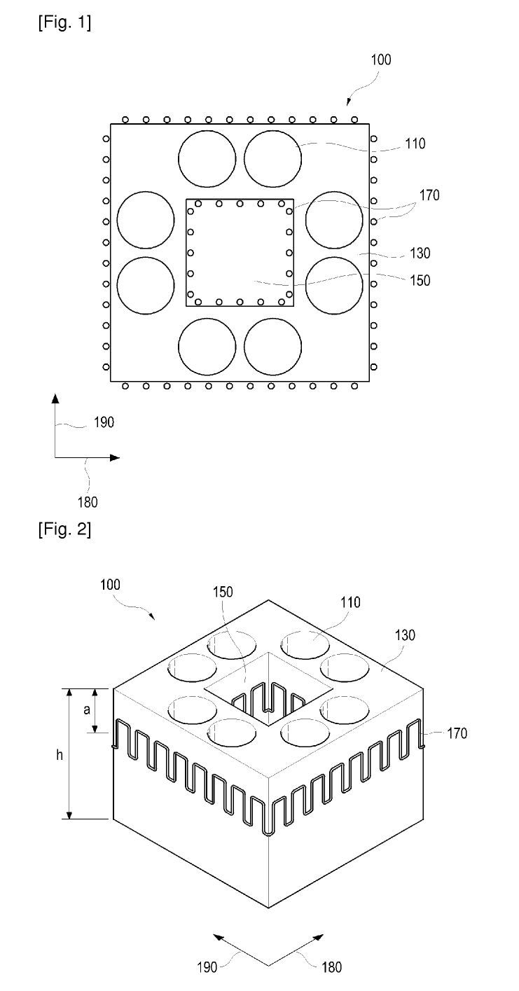

Referring to FIGS. 1 and 2, one embodiment of an apparatus 100 for depositing thin films over large-area substrates is illustrated. As shown, the apparatus 100 has a substantially rectangular shape and includes multiple point deposition sources 110 arranged in perpendicular directions 180, 190 to form, e.g., a two-dimensional array. The point deposition sources 110 may contain evaporation material, such as for example, organic material in the form of a solid or powder, which is evaporated at a predetermined elevated temperature. In certain embodiments, each of the point deposition sources 110 may contain different types of evaporation materials that are simultaneously deposited onto a substrate as a mixture.

The apparatus 100 may include a support member 130 to retain and support the point deposition sources 110 as shown in the embodiment of FIGS. 1 and 2. An aperture 150 may be formed within the support member 130 at or near the center of the support member 130. As illustrated, this embodiment of the support member 130 has a rectangular shape to allow the point deposition sources 110 to be arranged in a rectangular array.

In certain embodiments, the apparatus 100 may further include a heater 170 integrated with, encompassing, or in intimate contact with the support member 130. The heater 170 may be used to elevate the temperature of the point deposition sources 110 to vaporize the evaporation material contained therein. In selected embodiments, the heater 170 may generate heat using a resistive element such as a heater coil connected to a source of electrical current. The heat energy generated by the heater 170 may be conducted to the evaporation material contained in the point deposition sources 110 through the walls of the support member 130. This may vaporize the evaporation material and discharge it through openings of the point deposition sources 110 onto a deposition target, such as a substrate. The heater 170 may be positioned along an outer and inner surface of the support member 130 to conduct heat energy to the point deposition sources 110. In some embodiments, the thermal conductivity of the support member 130 is high enough to efficiently conduct heat energy to the deposition sources 110. For example, the support member 130 may be constructed of a thermally conductive material such as graphite, SiC, AlN, Al2O3, BN, quartz, Ti, stainless steel, or the like.

As shown in FIG. 2, the heater 170 may include several undulating coils along an outer and inner surface of the support member 130. The coils of the heater 170 are characterized by sufficient electrical resistance to generate heat energy in response to an electrical current flowing therethrough. Suitable materials for the coils of the heater 170 may include, for example, various ceramics, tantalum, tungsten, and compositions thereof.

In general, the temperature of the upper portion of the organic material in the point deposition sources 110 may be lower than that of the lower portion since the upper portion is open and exposed to air or other gases. To more uniformly heat the point deposition sources 110, the coils 170 may be placed a predetermined distance from the top of the support member 130. Thus, the coils of the heater 170 may be placed at a distance “a” from the top of the support member 130 where “h” represents the overall height of the support member 130. In one embodiment, “a” is approximately one-third of “h”. The effect is to decrease the temperature differences of the organic material in the upper and lower portions of the point deposition sources 110.

The shape and number of point deposition sources 110 may depend on the size of the substrate onto which the organic material is deposited. For example, a rectangular array of point deposition sources 110 may be best suited for depositing organic material onto a rectangular substrate. Similarly, a larger substrate may require additional point deposition sources 110 to uniformly deposit a thin film over the larger area. In selected embodiments, a substantially rectangular apparatus 100 in accordance with the present disclosure may be used to deposit uniform thin films for OLEDs having dimensions of, for example and not by way of limitation, 370 mm×470 mm, 600 mm×720 mm, 730 mm×920 mm, or the like. The point deposition sources 110 may also be designed to have adequate thermal conductivity to efficiently transfer heat from the heater 170 to the evaporation materials contained in the point deposition sources 110. In certain embodiments, these point deposition sources 110 may include a container or crucible to hold the organic materials. This container may be made of a thermally conductive material such as, for example and not by way of limitation, graphite, SiC, AlN, Al2O3, BN, quartz, Ti, stainless steel, or the like.

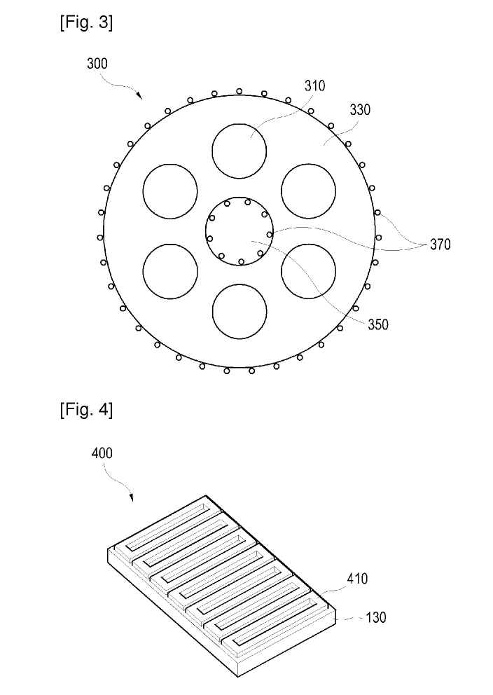

Referring to FIG. 3, one embodiment of a circular apparatus 300 is illustrated. Similar to the rectangular apparatus 100 of FIGS. 1 and 2, a circular apparatus 300 may include multiple point deposition sources 310, a support member 330, and an aperture 350 formed within the support member 330. Embodiments of the circular apparatus 300 may include heater coils 370 to heat the point deposition sources 310. These heater coils 370 may be disposed along an inner, outer, or both inner and outer surfaces of the support member 330.

As shown in FIG. 3, the support member 330 may have a circular shape to enable the point deposition sources 310 to be arranged in a circular pattern. In selected embodiments, the support member 330 has the shape of a cylinder. Similarly, the point deposition sources 310 may be arranged in one or more circumferential lines or other patterns around the cylinder. In certain cases, the pattern and number of the point deposition sources 310 may be tailored to the size and the shape of the target substrate onto which the organic material is deposited. Accordingly, the circular apparatus 300 may be used to uniformly deposit a thin film onto a circular substrate.

Referring to FIG. 4, one embodiment of an apparatus 400 having rows of linear deposition sources 410 is illustrated. The apparatus 400 includes a support member 130 and two or more linear deposition sources 410. As illustrated, the linear deposition sources 410 are arranged side-to-side in a row along the support member 130. Although the illustrated embodiment shows the linear deposition sources 410 arranged in rows, other patterns or arrangements are also possible such as two-dimensional arrays or radial patterns. Like the previous example, the linear deposition sources 410 may be used to deposit evaporation material onto a target substrate.

Similarly, each of the linear deposition sources 410 may discharge the same or different evaporation materials. A heater (not shown) may also be integrated into the apparatus 400. For example, a heater may be positioned between the linear deposition sources 410, along an outer surface of the support member 130, or a combination thereof. In general, the thermal conductivity of the support member 130 may be designed to efficiently transfer heat energy to the linear deposition sources 410. To achieve this end, the support member 130 may be constructed, for example, of thermally conductive materials such as graphite, SiC, AlN, Al2O3, BN, quartz, Ti stainless steel, or the like.

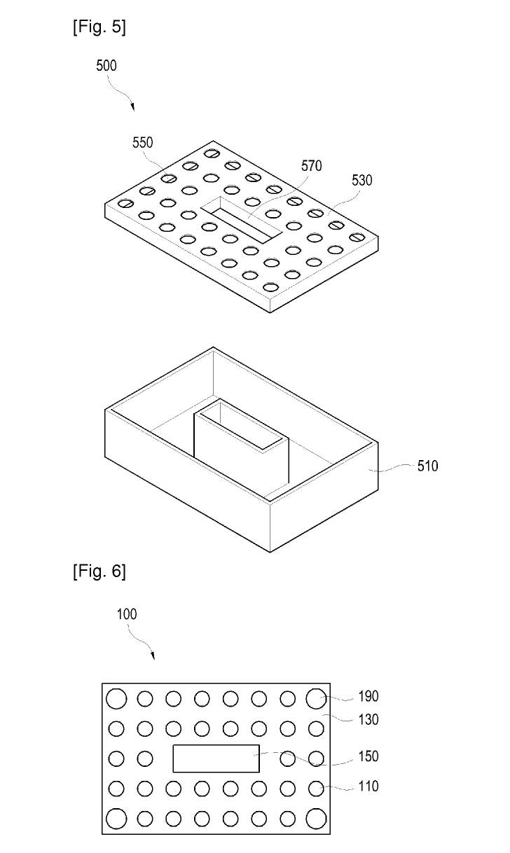

Referring to FIG. 5, another embodiment of an apparatus 500 in accordance with the present disclosure is illustrated. This embodiment includes a square crucible 510 and an upper cover 530 for capping the square crucible 510. The upper cover 530 may include multiple vapor outlets 550 having a circular, rectangular, elliptical, or other suitable shape. These vapor outlets 550 may be arranged in arrays or other patterns depending on the application. The square crucible 510 may contain an evaporation material, such as an organic material, that is evaporated, discharged through the vapor outlets 550, and deposited onto a substrate. Like the previous examples, this evaporation material may be vaporized at an elevated temperature by a heater (not shown).

In selected embodiments, the square crucible 510 may be constructed of an electrically insulative material such as quartz or ceramic materials. Like some of the previous examples, the apparatus 500 may be provided with an aperture 570. Similarly, in some embodiment, a heater may be disposed along an outer surface of the crucible 510 as well as along an inner surface of the aperture 570.

Referring to FIG. 6, in selected embodiments, the point deposition sources 110 may be provided in various sizes, shapes, or forms based upon the particular design requirements. For example, one embodiment of a rectangular apparatus 100 may include an array of point deposition sources 110 with larger point deposition sources 190 at the corners of the support member 130. In other embodiments, larger or smaller point deposition sources 110 may be positioned at other locations on the support member 130. These size differences may be selected based on factors such as substrate size, evaporative conditions, the type of evaporation materials being used, or the like. In selected embodiments, the rectangular apparatus 100 may also include an aperture 150 in the support member 130.

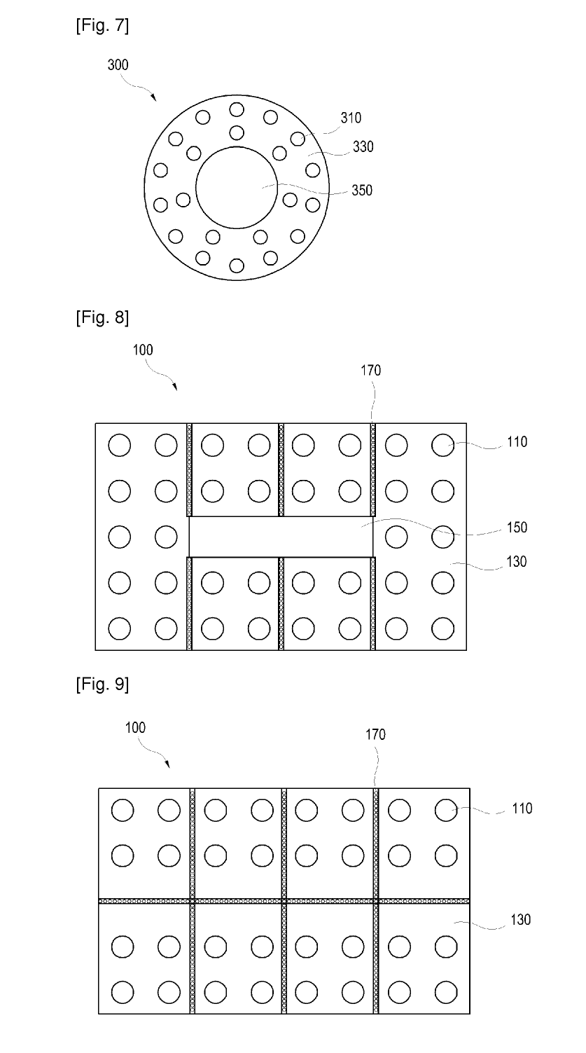

Referring to FIG. 7, an alternative embodiment of a circular apparatus 300 is illustrated. In this example, the apparatus 300 includes point deposition sources 310 arranged in circular patterns proximate an outer circumference and an inner circumference of the support member 330. In this example, the number of point deposition sources 310 along the outer circumference is greater than the number along the inner circumference. This arrangement may be used to equalize the density of point deposition sources 310 along the inner and outer circumference or be used to provide greater density along one of the inner and outer circumferences. These techniques may be used to provide improved film uniformity. The shape, size, and number of point deposition sources 310 may be varied according to the shape and size of the target substrate. In certain embodiments, the point deposition sources 310 may be arranged in more than two circumferential lines. Like the previous examples, the circular apparatus 300 may also include an aperture 350 at or near the center of the support member 330. In some embodiments, a heater (not shown) may also be provided along an outer surface of the support member 330, along an inner surface of the aperture 350, or both.

Referring to FIGS. 8 and 9, several embodiments of an apparatus 100 showing different methods of incorporating a heater therein are illustrated. In these examples, the apparatus 100 is rectangular and includes multiple point deposition sources 110 to deposit evaporation material onto a substrate. The apparatus 100 of FIG. 8 differs from that of FIG. 9 in that it includes an aperture 150. As previously described, a heater 170 may be installed along an outer surface of the support member 130 or along an inner surface such as inside the aperture 150. Furthermore, as shown, a heater 170 may also be embedded in the support member 130. This configuration may enable the point deposition sources 110 to be heated more uniformly by distributing the heat source throughout the support member 130.

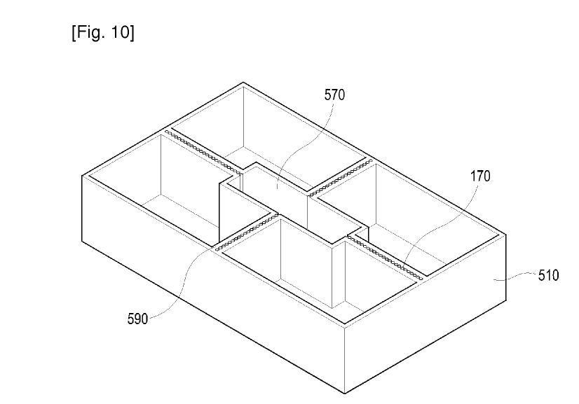

Referring to FIG. 10, one embodiment of a crucible 510 having a heater 170 embedded in sidewalls 590 thereof is illustrated. As shown, the crucible 510 includes a centrally located aperture 570 and sidewalls 590 dividing the crucible 510 into several sections, in this example, four sections. The crucible 510 may also include a heater (not shown) along an outer surface thereof or along an inner surface of the aperture 570. Additionally, as shown, a heater 170 may be integrated into the sidewalls 590 of the crucible 510 to enable more uniform heating of the evaporation materials contained therein. In selected embodiments, the heater 170 may include one or more resistive coils configured to heat the evaporation materials contained in the crucible 510.

Generally, the temperature of evaporation materials contained in an upper portion of the crucible 510 may tend to be lower than those contained in a lower portion because they are exposed to air or other gases. To provide more uniform heating, the coils may be placed closer to the top of the crucible 510 to reduce the temperature difference of evaporation materials in the upper and lower portions. The coils may be constructed of various materials including but not limited to ceramic, tantalum, tungsten, and compositions thereof.

Although the description provided herein includes description of apparatus having a rectangular or circular shape, the principles described herein may be readily applied to apparatus having many other shapes, such as eclipses, polygons, or the like. The shape chosen may depend on a number of factors such as, for example, the shape of the OLED substrate. Furthermore, although the deposition sources described herein are primarily arranged in a rectangular or circular pattern, the deposition sources may be arranged in myriad different arrangements, including but not limited to arrangement in rows, staggered or aligned patterns, radial patterns, or the like. Furthermore, the opening of each deposition source may take on various shapes including but not limited to rectangles, circles, ellipses, polygons, or the like.

The present disclosure may be embodied in other specific forms without departing from its basic features or characteristics. Thus, the described embodiments are to be considered in all respects only as illustrative, and not restrictive. The scope of the present disclosure is, therefore, indicated by the appended claims, rather than by the foregoing description. All changes within the meaning and range of equivalency of the claims are to be embraced within their scope.

1. An apparatus to heat evaporation material to form a thin film on a substrate, the apparatus comprising:
a plurality of deposition sources; and
a member to maintain the plurality of deposition sources in a selected arrangement.

2. The apparatus of claim 1, wherein each of the plurality of deposition sources is a point deposition source.

3. The apparatus of claim 1, wherein the plurality of deposition sources are disposed on a rectangular surface of the member.

4. The apparatus of claim 1, wherein the selected arrangement comprises rows of deposition sources.

5. The apparatus of claim 1, further comprising a heater to heat the plurality of deposition sources.

6. The apparatus of claim 1, wherein the plurality of deposition sources are arranged in a circular pattern.

7. The apparatus of claim 6, wherein the plurality of deposition sources are arranged in at least two concentric circular patterns.

8. The apparatus of claim 7, wherein the concentric circular patterns have different angular distributions.

9. The apparatus of claim 1, wherein each of the plurality of deposition sources is a linear deposition source.

10. The apparatus of claim 5, wherein the heater comprises a plurality of coils disposed along an outer and inner surface of the member.

11. The apparatus of claim 10, wherein the member is further characterized by a height, and the plurality of coils is placed about one third of the height from the surface.

12. The apparatus of claim 10, wherein the plurality of coils comprises a material selected from the group consisting of ceramic, tantalum, and tungsten.

13. The apparatus of claim 1, wherein the plurality of deposition sources comprise deposition sources of different sizes.

14. The apparatus of claim 1, wherein a size of each of the plurality of deposition sources is based on the position of the deposition source.

15. The apparatus of claim 1, wherein the member comprises a material selected from the group consisting of graphite, SiC, AlN, Al₂O₃, BN, quartz, Ti, and stainless steel.

16. The apparatus of claim 1, wherein each of the plurality of deposition sources comprises a container to contain evaporation material, the container comprising a material selected from the group consisting of graphite, SiC, AlN, Al₂O₃, BN, quartz, Ti, and stainless steel.

17. The apparatus of claim 1, wherein the member comprises an aperture.

18. The apparatus of claim 17, further comprising a heater wherein at least a position of the heater is disposed on an inner surface of the aperture and on an outer surface of the member.

19. The apparatus of claim 1, wherein the plurality of deposition sources accommodates different types of evaporation material.

20. An apparatus to heat an evaporation material, the apparatus comprising-
a container to accommodate evaporation material, the container having a first aperture;
a cover to cap an opening of the container and having a plurality of gas outlets and a second aperture to be aligned with the first aperture when the cover caps the opening; and
a heater having at least a position that is disposed along the inner surface of the first aperture and along an outer surface of the container.

21. The apparatus of claim 20, wherein the container comprises at least one sidewall.

22. The apparatus of claim 21, wherein the heater has a position that is embedded in the at least one sidewall.

23. The apparatus of claim 21, wherein the at least one sidewall divides the container into four sections.

24. The apparatus of claim 20, wherein the container comprises an electrically insulative material selected from the group consisting of quartz and a ceramic material.
